(19) United States
(12) Patent Application Publication
(10) Pub. No.: US 2024/0074158 A1
(43) Pub. Date: Feb. 29, 2024

(54) SHALLOW TRENCH ISOLATION RECESS CONTROL

(71) Applicant: Micron Technology, Inc., Boise, ID (US)

(72) Inventors: Chunhua Yao, Boise, ID (US); Song Guo, Boise, ID (US); Vivek Yadav, Boise, ID (US)

(21) Appl. No.: 18/234,145

(22) Filed: Aug. 15, 2023

Related U.S. Application Data
(60) Provisional application No. 63/402,187, filed on Aug. 30, 2022.

(51) Int. Cl. H10B 12/00

(52) U.S. Cl. CPC H10B 12/485; H10B 12/02

(57) ABSTRACT

A variety of applications can include an apparatus having a memory device in which, during fabrication of the memory device, processing a dielectric isolation region about an active area of a memory cell is controlled to provide enhanced electric isolation of a data line contact to the memory cell with respect to a cell contact to the memory cell. A portion of the dielectric isolation region can be recessed, creating a corner between the dielectric isolation region and a conductive region, where the conductive region is material for the active area. The corner can be filled with a dielectric material and the data line contact can be formed contacting the dielectric material and coupled to the conductive region. The cell contact can be formed to the memory cell contacting the dielectric material such that the dielectric material is between the cell contact and the data line contact.

### PRIORITY APPLICATION

This application claims the benefit of priority to U.S. Provisional Application Ser. No. 63/402,187, filed Aug. 30, 2022, which is incorporated herein by reference in its entirety.

### FIELD OF THE DISCLOSURE

Embodiments of the disclosure relate generally to memory systems and, more specifically, to memory devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a top view of a representation of contacts, data lines, and access lines for memory cells of an example array of a memory device, according to various embodiments.

FIGS. 2-9 illustrate features of an example process flow of shallow trench isolation recess control for data line contacts for a memory array of a memory device, according to various embodiments.

FIG. 10 shows a cross-sectional view of a structure indicating paths from the structure of FIG. 9 to components of a memory device, according to various embodiments.

FIG. 11 is a schematic of an example dynamic random-access memory device that can include a structure generated from shallow trench isolation recess control with respect to data line contacts, according to various embodiments.

FIG. 12 is a flow diagram of features of an example method of forming a memory device, according to various embodiments.

FIG. 13 is a flow diagram of features of an example method of forming a memory device, according to various embodiments.

FIG. 14 illustrates a block diagram of an example machine having one or more memory devices as discussed herein, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In DRAM processing, an effective starting configuration for fabricating conductive paths between capacitors of memory cells, active devices of the memory cells to access the capacitors, and data lines (e.g., bit lines) for the memory cells can include an interlayer dielectric (ILD) on shallow trench isolation (STI) regions about material for active areas, where the active areas are active areas of the active devices of the memory cells. STI regions are dielectric regions that separate active devices in an integrated circuit. The active devices can be transistors such as, but not limited to, metal-oxide-semiconductor (MOS) transistors or variations thereof. The ILD can be structured as multiple dielectric layers having different compositions and thickness selected according to the techniques for processing the conductive paths and associated structures. Ideally, the ILD is situated on tops of the STI regions and tops of the material for active areas that are at the same level, where exposing the material for active areas, to form contacts, would use a minimum over etch at the last etch of the ILD. However, the material for active areas between STIs tends to be rounded or tapered at the top of the material for active areas with material effectively from the ILD on top of the material for active areas extending to a bottom level of the ILD that is at the level of the top to the STI regions. Typically, to clear out this material on top of the material for active areas and expose the top of the material for active areas for further processing, an over etch significantly deeper into STI than the ideal case is conducted. Such processing can lead to creating a deep, large critical dimension (CD) metal region at the upper portion of the STI region, which can cause shorts at downstream processing of cell contacts for capacitors.

In various embodiments, shorting between a cell contact to a capacitor of a memory array of a memory device and a data line contact to a data line of the memory device can be avoided by STI recess control. STI recess control can include processing using a dielectric liner in which a dielectric corner from the dielectric liner remains after substantial removal of the dielectric liner, where the dielectric corner provides electrical isolation in contrast to procedures in which corners generated from STI recess are metal corners. The processing can include selective etching and corner liner fill. The selective etching process can include, but is not limited to, one or more dry etching procedures. The use of the dielectric liner in processing allows for control of data line contacts and STI recess. STI recess control can include application of a selective etch at the last layer of the ILD above the material for the active areas. With the material for an active area being a silicon region, the STI region being a dielectric nitride region, and the ILD having an oxide on the tops of the STI region and tops of the silicon region, the selective etch can include an oxide etch step in which oxide is etched with high selectivity to silicon but low selectivity to nitrogen rather than using an oxide etch with relatively low selectivity to both silicon and nitrogen. This etch selectivity allows for the removal of oxide and nitrogen as deep as appropriate, while leaving the silicon conductive region unetched.

The silicon region for an active area can be exposed for downstream processing as desired, regardless of its shape at the effective starting configuration of the ILD above the silicon region. The selective etching provides an opening that can be filled with dielectric liner. The dielectric liner can be formed by filling the opening with an atomic layer deposition (ALD) of a dielectric material. ALD is a monolayer by monolayer deposition techniques that can allow fabrication of thin layers of a number of monolayers to several nanometers of material and larger thickness of materials. ALD allows pinch off at the corner of the silicon region for the active area and the nitrogen STI region. The dielectric formed by ALD can be a non-oxide dielectric material. For example, the non-oxide dielectric material can be, but is not limited to, a dielectric nitride or silicon carbide. An isotropic removal of the dielectric material of the liner can be conducted, leaving a portion of the dielectric that filled the corner of the silicon conductive region with the nitride STI, while clearing out sacrificial sidewall portions of the dielectric liner and portions of the dielectric liner on top of the silicon of the active area. A wet etch can be conducted to perform the isotropic removal of the dielectric material. The portion of the dielectric liner remaining at the corner can provide electric insulation and prevent shorts at downstream processing.

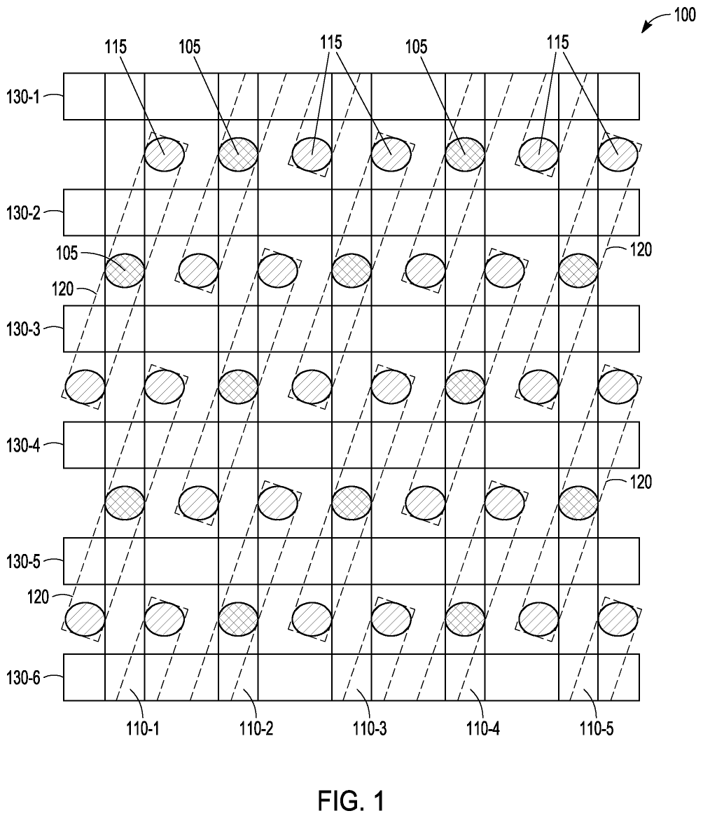

FIG. 1 is a top view of a representation of contacts, data lines, and access lines (e.g., word lines) for memory cells of an embodiment of an example array of a memory device 100. Memory device 100 can include access lines 130-1, 130-2, 130-3, 130-4, 130-5, and 130-6 to activate memory cells of memory device 100 and data lines 110-1, 110-2, 110-3, 110-4, and 110-5 to read data from or write data to storage units of the memory device 100. Though six access lines and five data lines are shown in FIG. 1, memory device 100 can include more than six access lines and more than five data lines. Memory device 100 can be, but is not limited to, a silicon-based DRAM device with capacitors as storage units. Each of data lines 110-1, 110-2, 110-3, 110-4, and 110-5 can couple to active regions 120 by an associated data line contact 105. Each active region 120 can include two unit cells having a common data line contact 105. Each of the two unit cells can include a storage node having a cell contact 115 coupled to an active area, where data line contact 105 is coupled to another active area of the unit cell. The active areas of the unit cell can be portions of a transistor. In FIG. 1, circular nodes that are shown for contact to data lines 110-1, 110-2, 110-3, 110-4, and 110-5 are data line contacts 105, and the circular nodes that are shown between access lines 130-1, 130-2, 130-3, 130-4, 130-5, and 130-6 without being shown in one of data lines 110-1, 110-2, 110-3, 110-4, and 110-5 are cell contacts 115. Other arrangements of data line contacts 105 and cell contacts 115 with respect to active regions 120 can be implemented. The number of data line contacts 105 and cell contacts 115 can be defined by the number of access lines and data lines as defined by the pattern shown in FIG. 1. Other arrangements can be implemented.

STI regions can be structured with respect to active regions 120. Processing data line contacts 105 and cell contacts 115 with respect to the STI regions can be conducted to reduce or prevent shorting between data line contacts 105 and adjacent cell contacts 115. For example, a data line contact 105 and an adjacent cell contact 115 between access line 130-1 and access line 130-2 with respect to data lines 110-1 and 110-2 are significantly close to each other, which can make these contacts susceptible to establishment of shorts between data line contacts 105 and adjacent cell contacts 115 during processing of memory device 100. Recess control of STIs associated with data line contact 105 can be implemented to significantly reduce the occurrence of such shorts.

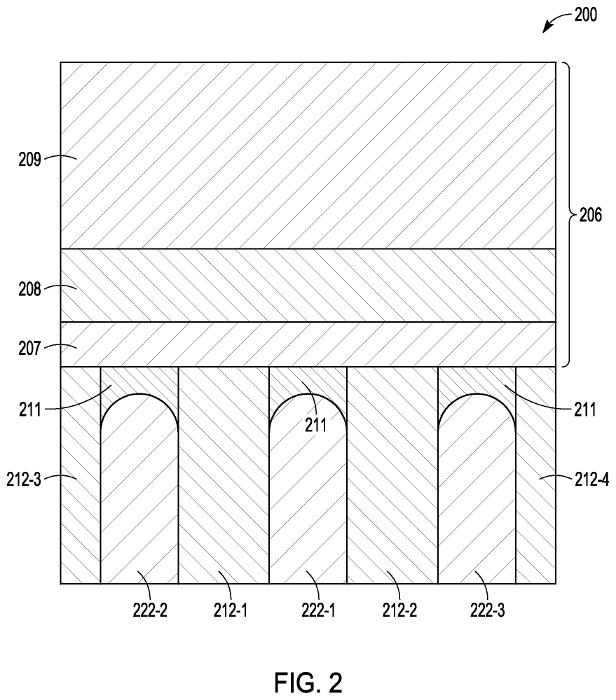

FIGS. 2-9 illustrate features of an embodiment of an example process flow of STI recess control for data line contacts for a memory array of a memory device. The techniques of FIGS. 2-9 can be used in the formation of data line contacts 105 of FIG. 1. FIG. 2 shows a cross-sectional view of a structure 200 after materials have been formed for the fabrication of a silicon-based memory device. Similar memory devices, other than silicon-based memory device, can be formed with techniques similar to those of FIGS. 2-9. An ILD 206 has been formed on STI 212-1, STI 212-2, STI 212-3, 212-4, and dielectrics 211. ILD 206 can include dielectric region 209, dielectric region 208, and dielectric region 207. Though shown with three dielectric regions, ILD 206 can have more or less than three dielectric regions. Dielectric region 209 can be an oxide region that can be, but is not limited to, a silicon oxide region. Dielectric region 208 can be a nitride region that can be, but is not limited to, a silicon nitride region. Dielectric region 207 can be an oxide region that can be, but is not limited to, a silicon oxide region. Other permutations of dielectric regions can be used. STI 212-1, STI 212-2, STI 212-3, 212-4 can be, but are not limited to, nitride regions. Such a nitride regions can be silicon nitride regions.

Silicon material for an active area (Si AA) 222-1 can be located between STI 212-1 and STI 212-2. A Si AA 222-2 can be located between STI 212-1 and STI 212-3. A Si AA 222-3 can be located between STI 212-2 and STI 212-4. Though Si AA 222-1, Si AA 222-2, and Si AA 222-3 are shown with rounded shapes, such material for active areas can be formed with ends that are tapered at the top of the material or have other shapes. Si AA 222-1, Si AA 222-2, and Si AA 222-3 can be formed with the formation of access devices that have been previously formed below ILD 206. Si AA 222-1, Si AA 222-2, and Si AA 222-3 are separated from dielectric region 207 by dielectrics 211. Dielectrics 211 can be formed at the time of formation of dielectric region 207 with material of dielectric region 207, though dielectrics 211 and the rounded or tapered ends of Si AA 222-1, Si AA 222-2, and Si AA 222-3 are not ideal. Subsequent processing, as taught herein, can mitigate the formation of dielectrics 211 along with providing electrical isolations between contact components.

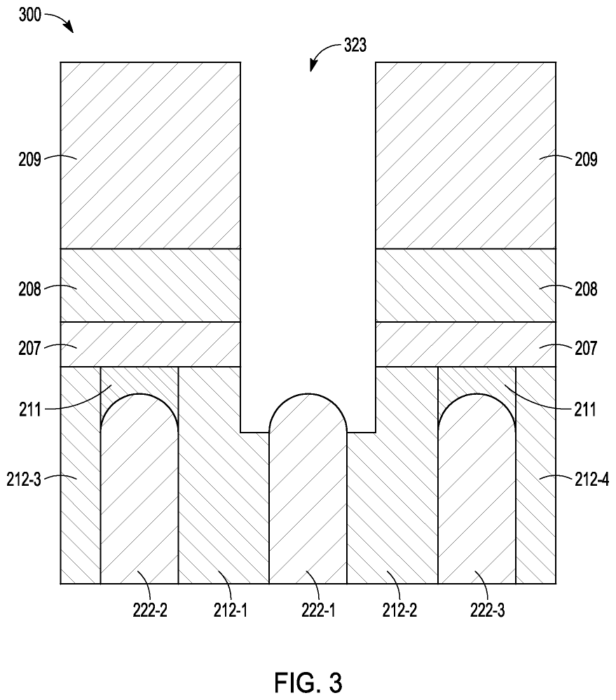

FIG. 3 shows a cross-sectional view of a structure 300 after processing structure 200 of FIG. 2. An opening 323 has been formed, exposing the tip of Si AA 222-1. Portions of STI 212-1 and 212-2 have been recessed by removal of material in exposing the tip such that the removal of the portions of STI 212-1 and STI 212-2 creates an open corner adjacent the exposed tip of Si AA 222-1. The tip of Si AA 222-1 can be exposed to a level at a few nanometers extending down from the top of the tip. Portions of dielectric region 209, dielectric region 208, and dielectric region 207 of ILD 206 have been removed. With ILD 206 being regions of a silicon oxide and a nitrogen oxide, the removal can be conducted using one or more etchants having a selectivity of oxygen and silicon being substantially greater than selectivity of oxygen and nitrogen. This etch selectivity allows removing oxygen and nitrogen as deep as desired, while leaving Si AA 222-1 unetched. Therefore, Si AA 222-1 is exposed for downstream processing as desired, regardless of the starting shape of Si AA 222-1 in structure 200 of FIG. 2.

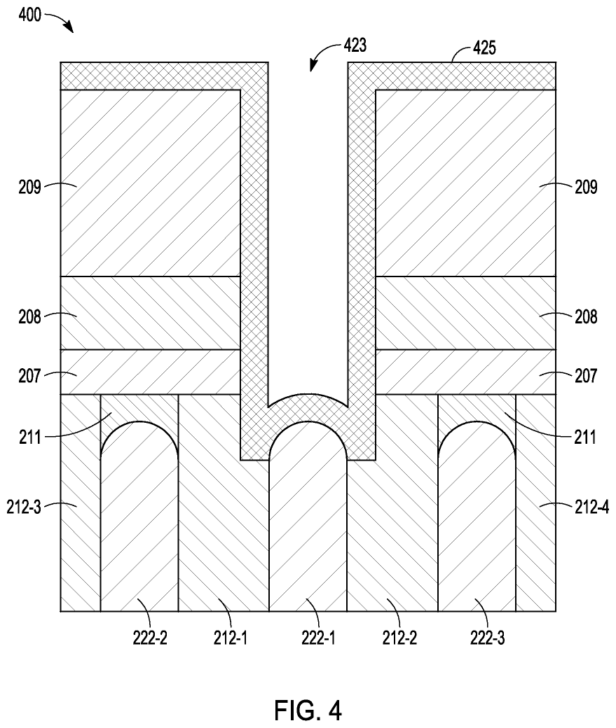

FIG. 4 shows a cross-sectional view of a structure 400 after processing structure 300 of FIG. 3. Opening 323 has been reduced in size by forming a dielectric 425 in opening 423, which forms opening 423. Dielectric 425 has been formed on the top surface of dielectric region 209, along sidewalls that defined opening 323 in structure 300, on the previously exposed tip of Si AA 222-1, and in the corner adjacent the previously exposed tip of Si AA 222-1. Dielectric 425 can be formed filling the corner. Dielectric 425 can be a dielectric material different from the material of dielectric region 209, dielectric region 208, dielectric region 207, STI 212-1, or 212-2. Dielectric 425 can be formed by ALD. Formation of dielectric 425 by ALD allows pinch off of dielectric 425 at the corner adjacent the previously exposed tip of Si AA 222-1. Dielectric 425 formed by ALD can be a non-oxide dielectric material. For example, the non-oxide dielectric material can be, but is not limited to, a dielectric nitride or silicon carbide.

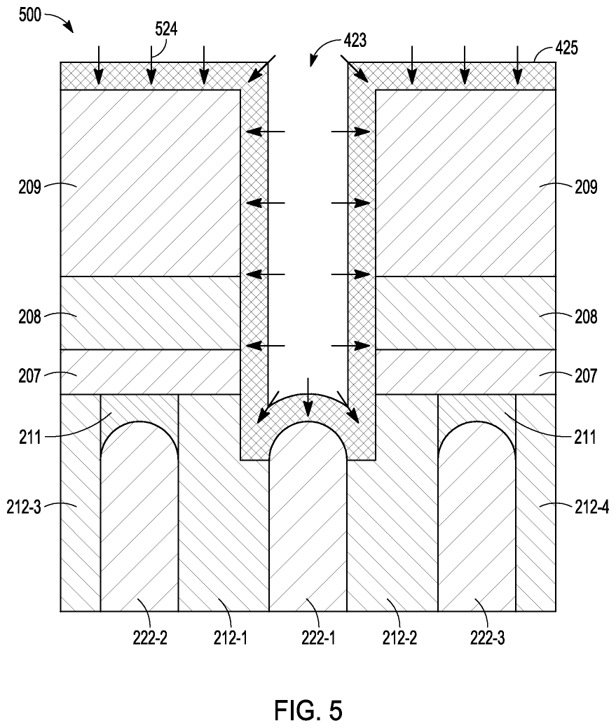

FIG. 5 shows a cross-sectional view of a structure 500 illustrating a processing of structure 400 of FIG. 4. An etchant 524 is being applied to dielectric 425. Etchant 524 can be selected to provide isotropic removal of substantially all of dielectric 425 such that a portion of dielectric 425 remains in corners between the tip of Si AA 222-1 and STIs 212-1 and 212-2. Isotropic etching can be provided by a wet etch technique.

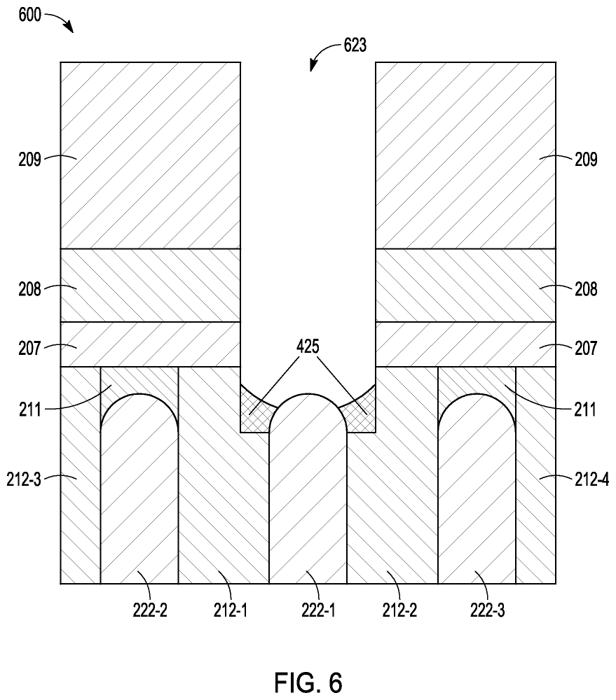

FIG. 6 shows a cross-sectional view of a structure 600 after processing of structure 500 of FIG. 5. An opening 623 results from removing the sacrificial material of dielectric 425, where opening 623 is an expansion of opening 423. The removed portions of dielectric 425 were sacrificial material for the process flow of FIGS. 2-9. The size of opening 623 can be returned to the size of opening 323 of FIG. 3 or another size. A portion of dielectric 425 remains in corners between the tip of Si AA 222-1 and STIs 212-1 and 212-2.

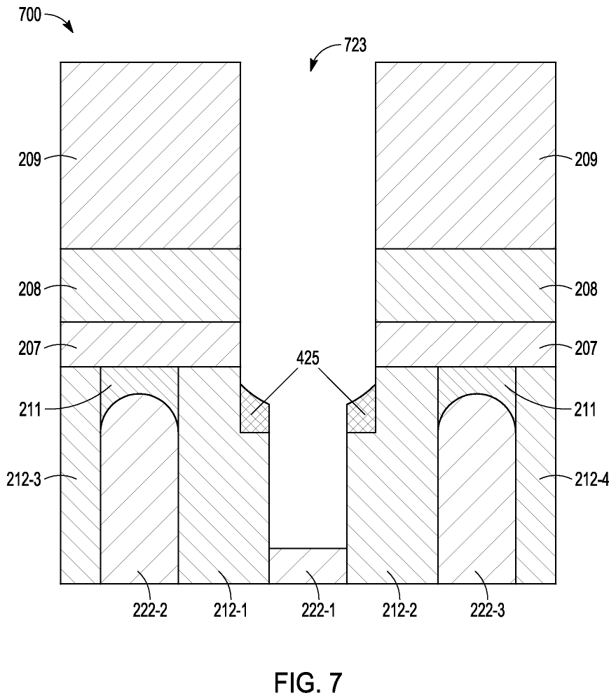

FIG. 7 shows a cross-sectional view of a structure 700 after processing structure 600 of FIG. 6. Si AA 222-1 has been recessed, generating an opening 723 that has an extended opening from opening 623 of FIG. 6. The extended opening can be a narrower opening. Recessing Si AA 222-1 can be conducted by applying an etching process. The etching process can be a vapor etch.

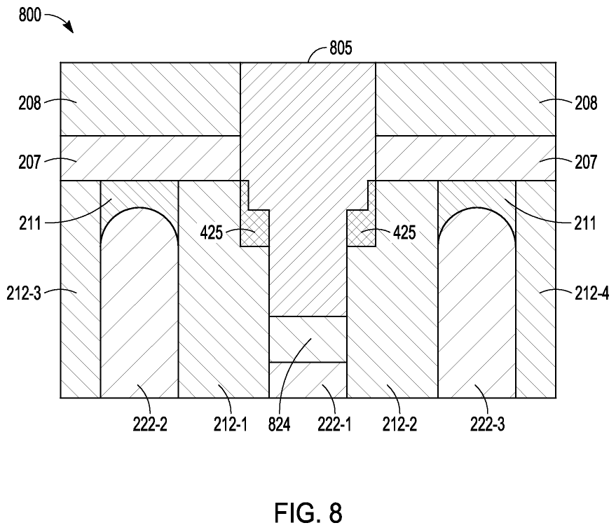

FIG. 8 shows a cross-sectional view of a structure 800 after processing structure 700 of FIG. 7. A polysilicon plug 824 has been formed on the recessed Si AA 222-1. Other conductive material other than silicon can be used for the plug. Polysilicon plug 824 can be formed by a polysilicon fill process followed by an etch back of the filled polysilicon. The etch back can be to a selected level below the bottom level of dielectric 425 in the previously formed corners with STIs 212-1 and 212-2. A data line contact 805 has been formed on polysilicon plug 824 and on dielectric 425 in the previously formed corners with STIs 212-1 and 212-2. Dielectrics 425 contacts data line contact 805 and STIs 212-1 and 212-2. Data line contact 805 can be formed by filling opening 723 from polysilicon plug 824 and etching back the material of data line contact 805 to a desired level. Data line contact 805 can be a region of one or more metallic materials. A metallic material is a composition of one or more elemental metals or a composition of two or more elements such that the composition has electrical properties of a metal. A metallic material can be structured having one or more elemental metals and one or more non-metal elements. Data line contact 805 can include, but is not limited to, tungsten. Dielectric region 209, which was formed as sacrificial material for performing the process flow of FIGS. 2-9, has been removed.

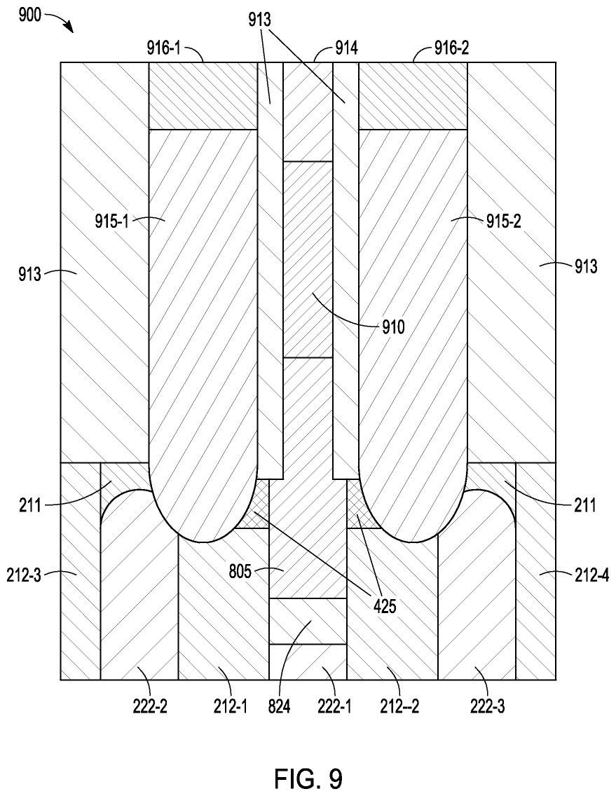

FIG. 9 shows a cross-sectional view of a structure 900 after processing structure 800 of FIG. 8. A data line 910 has been formed connected to data line contact 805. A cell contact 915-1 has been formed connected to Si AA 222-2 and a cell contact 915-2 has been formed connected to Si AA 222-3. Dielectric regions 208 and 207, which were formed as sacrificial material for performing the process flow of FIGS. 2-9, have been removed. A conductive region 916-1 has been formed on cell contact 915-1 and a conductive region 916-2 has been formed on cell contact 915-2. Conductive regions 916-1 and 916-2 can be formed as part of a path for routing signals. A conductive region 914 has been formed on data line contact 805, which can be used for signaling routing. An isolation dielectric 913 has been formed around conductive regions 916-1 and 916-2, cell contacts 915-1 and 915-2, conductive region 914, data line 910, and data line contact 805. Data line contact 805 can be formed as data line contacts 105 of memory device 100 of FIG. 1 and cell contacts 915-1 and 915-2 can be formed as cell contacts 115 of memory device 100 of FIG. 1.

Various deposition techniques for components of structures 200-900 in the process flow of FIGS. 2-9 can be used that are typical for the material being formed, the dimensions of the material being formed, and the architecture in which the material is being formed. Processes for forming the various materials can include, but are not limited to, chemical vapor deposition (CVD), ALD, and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing discussed with respect to FIGS. 2-9. Etching procedures can include, but are not limited to, wet etching, dry etching, and atomic layer etching deposition, among others.

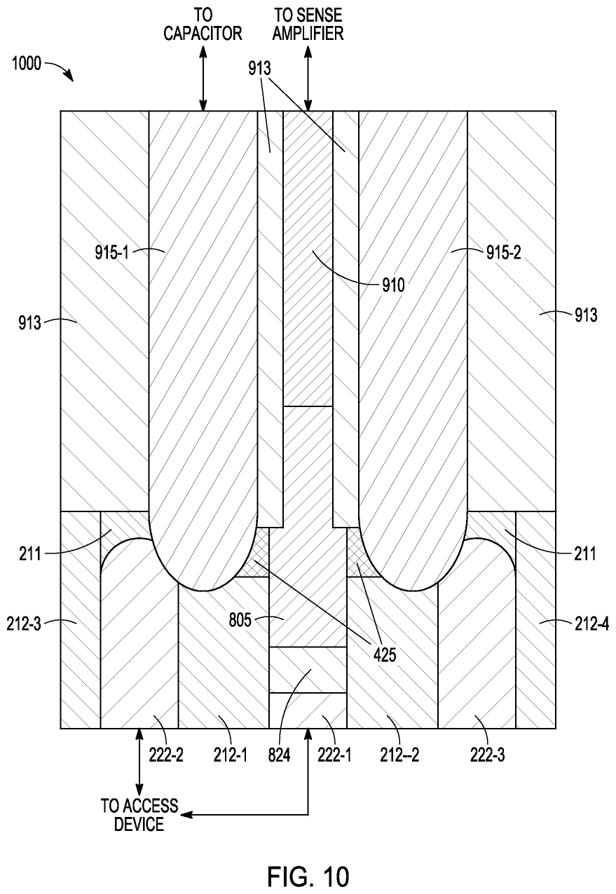

FIG. 10 shows a cross-sectional view of a structure 1000 indicating paths from structure 900 to components of a memory device. Cell contact 915-1 can be coupled to a capacitor that is implemented as a storage cell for data. Cell contact 915-1 connects to Si AA 222-2 for an access device that includes Si AA 222-1. With respect to the cross-sectional view of FIG. 10, other components of the access device can be viewed in a plane parallel to that of FIG. 10. Si AA 222-1 via polysilicon plug 824 is coupled to data line contact 805 connected to data line 910. Data line 910 can be coupled to a sense amplifier.

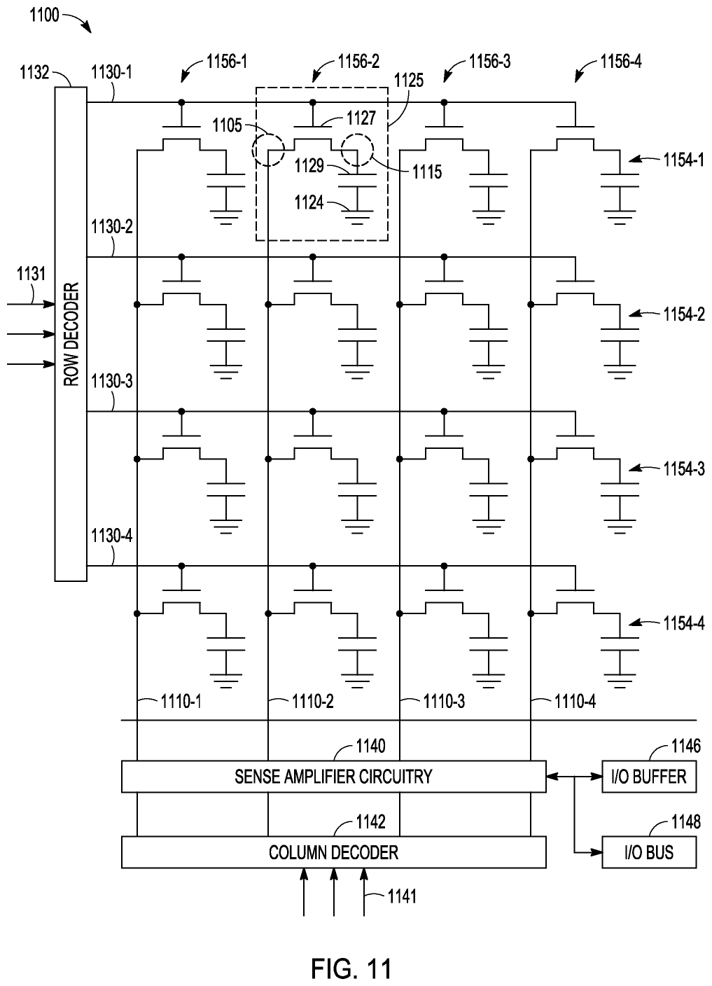

FIG. 11 is a schematic of an embodiment of an example DRAM device 1100 that can include data line contacts and cell contacts separated by a dielectric corner that provide enhanced electrical isolation, as taught herein. DRAM device 1100 includes an array of memory cells 1125 (only one being labeled in FIG. 11 for ease of presentation) arranged in rows 1154-1, 1154-2, 1154-3, and 1154-4 and columns 1156-1, 1156-2, 1156-3, and 1156-4. For simplicity and ease of discussion, the array is shown in only two dimensions, but the array can be extended into the third dimension. Further, while only four rows 1154-1, 1154-2, 1154-3, and 1154-4 and four columns 1156-1, 1156-2, 1156-3, and 1156-4 of four memory cells are illustrated, DRAM devices like DRAM device 1100 can have significantly more memory cells 1125 (e.g., tens, hundreds, or thousands of memory cells) per row or per column.

Each memory cell 1125 can include a single transistor 1127 and a single capacitor 1129, which is commonly referred to as a 1T1C (one-transistor-one capacitor cell). One plate of capacitor 1129, which can be termed the “node plate,” is connected to the drain terminal of transistor 1127, whereas the other plate of the capacitor 1129 is connected to ground 1124. Each capacitor 1129 within the array of 1T1C memory cells 1125 typically serves to store one bit of data, and the respective transistor 1127 serves as an access device to write to or read from storage capacitor 1129.

The transistor gate terminals within each row of rows 1154-1, 1154-2, 1154-3, and 1154-4 are portions of respective access lines 1130-1, 1130-2, 1130-3, and 1130-4 (for example, word lines), and the transistor source terminals within each of columns 1156-1, 1156-2, 1156-3, and 1156-4 are electrically connected to respective data lines 1110-1, 1110-2, 1110-3, and 1110-4 (for example bit lines). The connection of a data line, such as data line 1110-2, to a memory cell, such as dotted memory cell 1125, can be made using a data line contact 1105. Data line contact 1105 can be structured similar to data line contact 105 of FIG. 1 and data line contact 805 of FIGS. 9 and 10. Transistor 1127 can be connected to capacitor 1129 by a cell contact 1115. Cell contact 1115 can be structured similar to cell contact 115 of FIG. 1 and cell contact 915-1 of FIGS. 9 and 10. The arrangement of data line contact 1105, cell contact 1115, transistor 1127, and capacitor 1129 illustrates the operational relationship of the components of FIGS. 9 and 10.

A row decoder 1132 can selectively drive the individual access lines 1130-1, 1130-2, 1130-3, and 1130-4, responsive to row address signals 1131 input to row decoder 1132. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier circuitry 1140, which can transfer bit values between the memory cells 1125 of the selected row of the rows 1154-1, 1154-2, 1154-3, and 1154-4 and input/output buffers 1146 (for write/read operations) or external input/output data buses 1148.

A column decoder 1142 responsive to column address signals 1141 can select which of the memory cells 1125 within the selected row is read out or written to. Alternatively, for read operations, the storage capacitors 1129 within the selected row may be read out simultaneously and latched, and the column decoder 1142 can then select which latch bits to connect to the output data bus 1148. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 1100 may be implemented as an integrated circuit within a package that includes pins for receiving supply voltages (e.g., to provide the source and gate voltages for the transistors 1127) and signals (including data, address, and control signals). FIG. 11 depicts DRAM device 1100 in simplified form to illustrate basic structural components, omitting many details of the memory cells 1125 and associated access lines 1130-1, 1130-2, 1130-3, and 1130-4 and data lines 1110-1, 1110-2, 1110-3, and 1110-4 as well as the peripheral circuitry. For example, in addition to the row decoder 1132 and column decoder 1142, sense amplifier circuitry 1140, and buffers 1146, DRAM device 1100 may include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 1154-1, 1154-2, 1154-3, and 1154-4 and columns 1156-1, 1156-2, 1156-3, and 1156-4 of memory cells 1125 are arranged along a single horizontal plane (i.e., a plane parallel to the layers) of the semiconductor substrate, e.g., in a rectangular lattice with mutually perpendicular horizontal access lines 1130-1, 1130-2, 1130-3, and 1130-4 and data lines 1110-1, 1110-2, 1110-3, and 1110-4. In 3D DRAM arrays, the memory cells 1125 are arranged in a 3D lattice that encompasses multiple vertically stacked horizontal planes corresponding to multiple device tiers of a multi-tier substrate assembly, with each device tier including multiple parallel rows of memory cells 1125 whose transistor gate terminals are connected by horizontal access lines such as access lines 1130-1, 1130-2, 1130-3, and 1130-4. A “device tier,” as used herein, may include multiple layers (or levels) of materials, but forms the components of memory devices of a single horizontal tier of memory cells. Data lines 1110-1, 1110-2, 1110-3, and 1110-4 can extend vertically through all or at least a vertical portion of the multi-tier structure, and each of the data lines 1110-1, 1110-2, 1110-3, and 1110-4 can connect to the transistor source terminals of respective vertical columns 1156-1, 1156-2, 1156-3, and 1156-4 of associated memory cells 1125 at the multiple device tiers. Such a 3D configuration of memory cells enables further increases in bit density compared with 2D arrays.

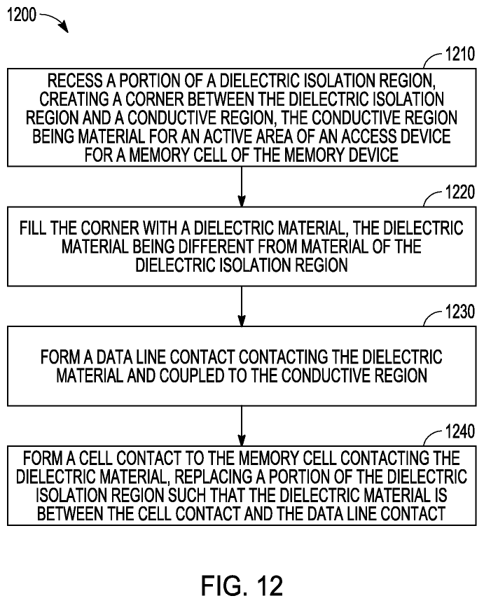

FIG. 12 is a flow diagram of features of an embodiment of an example method 1200 of forming a memory device. At 1210, a portion of a dielectric isolation region is recessed, creating a corner between the dielectric isolation region and a conductive region. The conductive region is a material for an active area of an access device for a memory cell of the memory device. At 1220, the corner is filled with a dielectric material, where the dielectric material is different from material of the dielectric isolation region. Filling the corner with the dielectric material can include forming the dielectric material by atomic layer deposition. The dielectric material can be a non-oxide dielectric. The non-oxide dielectric can include one or more of a dielectric nitride or silicon carbide.

At 1230, a data line contact is formed contacting the dielectric material and coupled to the conductive region. At 1240, a cell contact to the memory cell is formed contacting the dielectric material, replacing a portion of the dielectric isolation region such that the dielectric material is between the cell contact and the data line contact.

Variations of method 1200 or methods similar to method 1200 can include a number of different embodiments that may be combined depending on the application of such methods and/or the architecture of systems in which such methods are implemented. Such methods can include forming a silicon plug between the data line contact and the conductive region after recessing the conductive region in a procedure to form the data line contact to the conductive region. Variations can include forming a capacitor coupled to the cell contact.

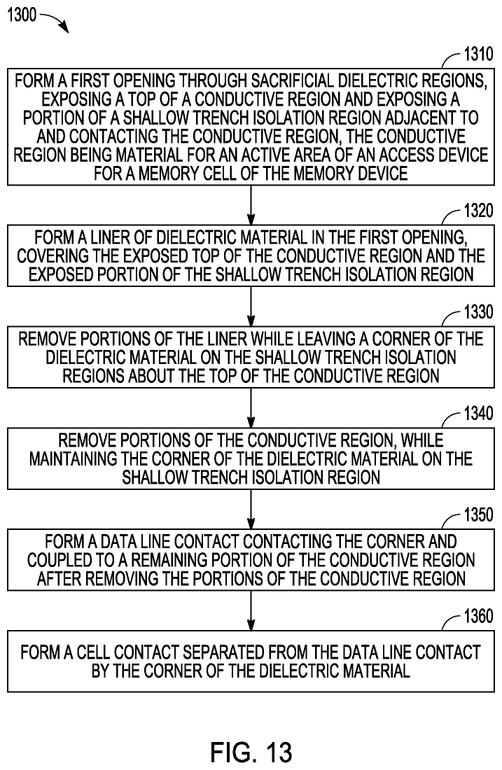

FIG. 13 is a flow diagram of features of an embodiment of an example method 1300 of forming a memory device. At 1310, a first opening is formed through sacrificial dielectric regions, exposing a top of a conductive region and exposing a portion of a shallow trench isolation region adjacent to and contacting the conductive region. The conductive region is material for an active area of an access device for a memory cell of the memory device. The shallow trench isolation region can include a dielectric nitride. Forming the first opening can include selectively etching the sacrificial dielectric regions substantially without etching the conductive region.

At 1320, a liner of dielectric material is formed in the first opening. The formed liner covers the exposed top of the conductive region and the exposed portion of the shallow trench isolation region. Forming the liner of dielectric material can include forming the liner by atomic layer deposition. The dielectric material can be a non-oxide dielectric. The non-oxide dielectric can include one or more of a dielectric nitride or silicon carbide.

At 1330, portions of the liner are removed while leaving a corner of the dielectric material on the shallow trench isolation regions about the top of the conductive region. At 1340, portions of the conductive region are removed, while maintaining the corner of the dielectric material on the shallow trench isolation region. Removing the portions of the liner can include performing an isotropic removal of the portions of the liner. The isotropic removal can include performing a wet etch of the liner.

At 1350, a data line contact is formed contacting the corner and coupled to a remaining portion of the conductive region after removing the portions of the conductive region. At 1360, a cell contact is formed, where the cell contact is separated from the data line contact by the corner of the dielectric material.

Variations of method 1300 or methods similar to method 1300 can include a number of different embodiments that may be combined depending on the application of such methods and/or the architecture of systems in which such methods are implemented. Such methods can include forming the data line contact by forming a conductive plug contacting the remaining portion of the conductive region and forming the data line contact above and contacting the conductive plug. The conductive plug can be a polysilicon plug and the data line contact can include tungsten. Other materials can be used for the conductive plug and data line contact depending on the materials selected for forming the memory device.

In various embodiments, a memory device can include a memory cell having a storage element and an access device, a data line contact coupled to the access device of the memory cell, and a cell contact coupled to the access device of the memory cell. A shallow trench isolation region is situated adjacent to and contacting the data line contact. A dielectric structure can contact the data line contact and the cell contact, where the dielectric structure is on and contacting the shallow trench isolation region and separates the data line contact from the cell contact.

Variations of such a memory device and its features, as taught herein, can include a number of different embodiments and features that may be combined depending on the application of such memory devices, the format of such memory devices, and/or the architecture in which such memory devices are implemented. Features of such memory devices can include the dielectric structure being a non-oxide dielectric. The non-oxide dielectric can include one or more of a dielectric nitride, silicon carbide, or other materials. Variations can include the data line contact connected to a metallic data line. The metallic data line can be, but is not limited to, tungsten. Variations can include the access device being a transistor and the storage element can be a capacitor.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

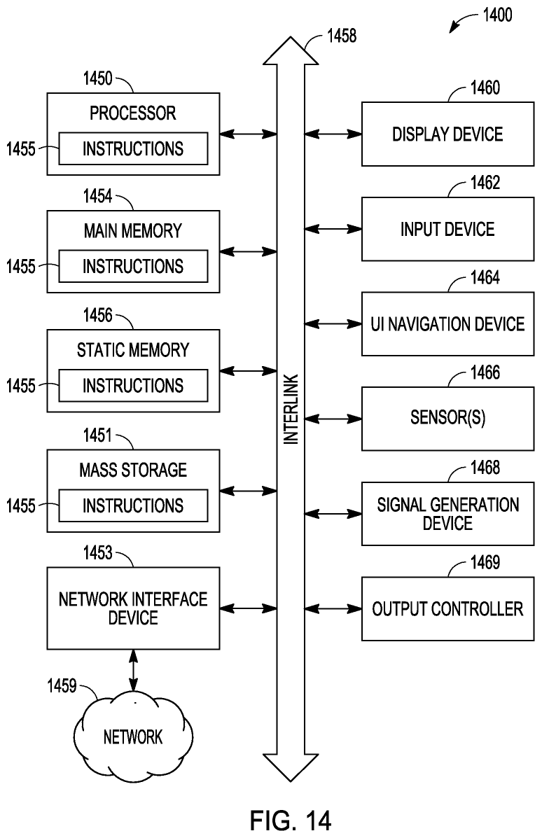

FIG. 14 illustrates a block diagram of an embodiment of an example machine 1400 having one or more memory devices as discussed herein. In alternative embodiments, machine 1400 can operate as a standalone device or can be connected (e.g., networked) to other machines. In a networked deployment, machine 1400 can operate in the capacity of a server machine, a client machine, or both in server-client network environments. In an example, machine 1400 can act as a peer machine in peer-to-peer (P2P) (or other distributed) network environment. Machine 1400 can be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more methodologies such as cloud computing, software as a service (SaaS), other computer cluster configurations.

Examples, as described herein, can include, or can operate by, logic, components, devices, packages, or mechanisms. Circuitry is a collection (e.g., set) of circuits implemented in tangible entities that include hardware (e.g., simple circuits, gates, logic, etc.). Circuitry membership can be flexible over time and underlying hardware variability. Circuitries include members that can, alone or in combination, perform specific tasks when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a computer readable medium physically modified (e.g., magnetically, electrically, moveable placement of invariant massed particles, etc.) to store instructions of the specific operation. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components can be used in more than one member of more than one circuitry.

The machine 1400 can include a hardware processor 1450 (e.g., a CPU, a GPU, a hardware processor core, or any combination thereof), a main memory 1454, and a static memory 1456, some or all of which can communicate with each other via an interlink 1458 (e.g., bus). Machine 1400 can further include a display device 1460, an input device 1462, which can be an alphanumeric input device (e.g., a keyboard), and a user interface (UI) navigation device 1464 (e.g., a mouse). In an example, display device 1460, input device 1462, and UI navigation device 1464 can be a touch screen display. Machine 1400 can additionally include a mass storage device (e.g., drive unit) 1451, a network interface device 1453, a signal generation device 1468, and one or more sensors 1466, such as a global positioning system (GPS) sensor, compass, accelerometer, or other sensor. Machine 1400 can include an output controller 1469, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Machine 1400 can include one or more machine-readable media on which is stored one or more sets of data structures or instructions 1455 (e.g., software, microcode, or other type of instructions) embodying or utilized by machine 1400 to perform any one or more of the techniques or functions for which machine 1400 is designed. The instructions 1455 can reside, completely or at least partially, within main memory 1454, within static memory 1456, or within hardware processor 1450 during execution thereof by machine 1400. In an example, one or any combination of hardware processor 1450, main memory 1454, static memory 1456, or mass storage device 1451 can constitute the machine-readable media on which is stored one or more sets of data structures or instructions. Various ones of hardware processor 1450, main memory 1454, static memory 1456, or mass storage device 1451 can include one or more antifuses using components of a FinFET architecture as discussed herein.

While an example machine-readable medium is illustrated as a single medium, the term “machine-readable medium” can include a single medium or multiple media (e.g., a centralized or distributed database, or associated caches and servers) configured to store instructions 1455 or data. The term “machine-readable medium” can include any medium that is capable of storing instructions for execution by machine 1400 and that cause machine 1400 to perform any one or more of the techniques to which machine 1400 is designed, or that is capable of storing data structures used by or associated with such instructions. Non-limiting machine-readable medium examples can include solid-state memories, optical media, and magnetic media. Specific examples of non-transitory machine-readable media can include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

Instructions 1455 (e.g., software, programs, an operating system (OS), etc.) or other data stored on mass storage device 1451 can be accessed by main memory 1454 for use by hardware processor 1450. Main memory 1454 (e.g., DRAM) is typically fast, but volatile, and thus a different type of storage than mass storage device 1451 (e.g., an SSD), which is suitable for long-term storage, including while in an “off” condition. Instructions 1455 or data in use by a user or machine 1400 are typically loaded in main memory 1454 for use by hardware processor 1450. When main memory 1454 is full, virtual space from mass storage device 1451 can be allocated to supplement main memory 1454; however, because mass storage device 1451 is typically slower than main memory 1454, and write speeds are typically at least twice as slow as read speeds, use of virtual memory can greatly reduce user experience due to storage device latency (in contrast to main memory 1454, e.g., DRAM). Further, use of mass storage device 1451 for virtual memory can greatly reduce the usable lifespan of mass storage device 1451.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

Instructions 1455 can further be transmitted or received over a network 1459 using a transmission medium via signal generation device 1468 or network interface device 1453 utilizing any one of a number of transfer protocols (e.g., frame relay, Internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, signal generation device 1468 or network interface device 1453 can include one or more physical jacks (e.g., Ethernet, coaxial, or phone jacks) or one or more antennas to connect to network 1459. In an example, signal generation device 1468 or network interface device 1453 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by machine 1400 or data to or from machine 1400, and can include instrumentalities to propagate digital or analog communications signals to facilitate communication of such instructions, which instructions may be implemented by software or data.

The following are example embodiments of methods and devices, in accordance with the teachings herein.

An example method 1 of forming a memory device can comprise recessing a portion of a dielectric isolation region, creating a corner between the dielectric isolation region and a conductive region, the conductive region being material for an active area of an access device for a memory cell of the memory device; filling the corner with a dielectric material, the dielectric material being different from material of the dielectric isolation region; forming a data line contact contacting the dielectric material and coupled to the conductive region; forming a cell contact to the memory cell contacting the dielectric material, replacing a portion of the dielectric isolation region such that the dielectric material is between the cell contact and the data line contact.

An example method 2 of forming a memory device can include features of example method 1 of forming a memory device and can include filling the corner with the dielectric material to include forming the dielectric material by atomic layer deposition.

An example method 3 can include features of example method 2 of forming a memory device and features of any of the preceding example methods of forming a memory device and can include the dielectric material being a non-oxide dielectric.

An example method 4 of forming a memory device can include features of any of the preceding example methods of forming a memory device and can include forming the data line contact to the conductive region to include forming a silicon plug between the data line contact and the conductive region after recessing the conductive region.

An example method 5 can include features of any of the preceding example methods of forming a memory device and can include forming a capacitor coupled to the cell contact.

In an example method 6 of forming a memory device, any of the example methods 1 to 5 of forming a memory device may be performed to structure an electronic memory apparatus further comprising a host processor and a communication bus extending between the host processor and a memory device.

In an example method 7 of forming a memory device, any of the example methods 1 to 6 of forming a memory device may be modified to include operations set forth in any other of method examples 1 to 6 of forming a memory device.

In an example method 8 of forming a memory device, any of the example methods 1 to 7 of forming a memory device may be implemented at least in part through use of instructions stored as a physical state in one or more machine-readable storage devices.

An example method 9 of forming a memory device can include features of any of the preceding example methods 1 to 8 of forming a memory device and can include performing functions associated with any features of example electronic devices 1 to 8 of forming a memory device.

An example method 10 of forming a memory device can comprise forming a first opening through sacrificial dielectric regions, exposing a top of a conductive region and exposing a portion of a shallow trench isolation region adjacent to and contacting the conductive region, the conductive region being material for an active area of an access device for a memory cell of the memory device; forming a liner of dielectric material in the first opening, covering the exposed top of the conductive region and the exposed portion of the shallow trench isolation region; removing portions of the liner while leaving a corner of the dielectric material on the shallow trench isolation regions about the top of the conductive region; removing portions of the conductive region, while maintaining the corner of the dielectric material on the shallow trench isolation region; forming a data line contact contacting the corner and coupled to a remaining portion of the conductive region after removing the portions of the conductive region; and forming a cell contact separated from the data line contact by the corner of the dielectric material.

An example method 11 of forming a memory device can include features of example method 10 of forming a memory device and can include forming the first opening to include selectively etching the sacrificial dielectric regions substantially without etching the conductive region.

An example method 12 can include features of any of the preceding example methods 10-11 of forming a memory device and can include forming the liner of dielectric material to include forming the liner by atomic layer deposition.

An example method 13 can include features of any of the preceding example methods 10-12 of forming a memory device and can include removing the portions of the liner to include performing an isotropic removal of the portions of the liner.

An example method 14 of forming a memory device can include features of example method 13 and any of the preceding example methods 10-12 of forming a memory device and can include performing the isotropic removal to include performing a wet etch of the liner.

An example method 15 of forming a memory device can include features of any of the preceding example methods 10-14 of forming a memory device and can include the dielectric material being a non-oxide dielectric.

An example method 16 of forming a memory device can include features of example method 15 and any of the preceding example methods 10-15 of forming a memory device and can include the non-oxide dielectric being one or more of a dielectric nitride or silicon carbide.

An example method 17 of forming a memory device can include features of any of the preceding example methods 10-16 of forming a memory device and can include forming the data line contact to include forming a conductive plug contacting the remaining portion of the conductive region, and forming the data line contact above and contacting the conductive plug.

An example method 18 of forming a memory device can include features of example method 15 and any of the preceding example methods of forming a memory device and can include the conductive plug being a polysilicon plug and the data line contact to include tungsten.

An example method 19 of forming a memory device can include features of any of the preceding example methods 10-18 of forming a memory device and can include the shallow trench isolation region to include a dielectric nitride.

In an example method 20 of forming a memory device, any of the example methods 12 to 19 of forming a memory device may be performed to structure an electronic memory apparatus further comprising a host processor and a communication bus extending between the host processor and the memory device.

In an example method 21 of forming a memory device, any of the example methods 12 to 20 of forming a memory device may be modified to include operations set forth in any other of method examples 12 to 20 of forming a memory device.

In an example method 22 of forming a memory device, any of the example methods 12 to 21 of forming a memory device may be modified to include operations set forth in any other of method examples 1 to 11 of forming a memory device.

In an example method 23 of forming a memory device, any of the example methods 12 to 22 of forming a memory device may be implemented at least in part through use of instructions stored as a physical state in one or more machine-readable storage devices.

An example method 24 of forming a memory device can include features of any of the preceding example methods 12 to 23 of forming a memory device and can include performing functions associated with any features of example memory devices 1 to 9.

An example memory device 1 can comprise: a memory cell having a storage element and an access device; a data line contact coupled to the access device of the memory cell; a cell contact coupled to the access device of the memory cell; a shallow trench isolation region adjacent to and contacting the data line contact; and a dielectric structure contacting the data line contact and the cell contact, the dielectric structure on and contacting the shallow trench isolation region and separating the data line contact from the cell contact.

An example memory device 2 can include features of example memory device 1 and can include the dielectric structure being a non-oxide dielectric.

An example memory device 3 can include features of example memory device 2 and features of any of the preceding example memory devices and can include the non-oxide dielectric to include one or more of a dielectric nitride or silicon carbide.

An example memory device 4 can include features of any of the preceding example memory devices and can include the data line contact being connected to a metallic data line.

An example memory device 5 can include features of any of the preceding example memory devices and can include the access device being a transistor and the storage element being a capacitor.

In an example memory device 6, any of the memory devices of example memory devices 1 to 5 may include memory devices incorporated into an electronic memory apparatus further comprising a host processor and a communication bus extending between the host processor and the memory device.

In an example memory device 7, any of the memory devices of example memory devices 1 to 6 may be modified to include any structure presented in another of example memory device 1 to 6.

In an example memory device 8, any apparatus associated with the memory devices of example memory devices 1 to 7 may further include a machine-readable storage device configured to store instructions as a physical state, wherein the instructions may be used to perform one or more operations of the apparatus.

In an example memory device 9, any of the memory devices of example memory devices 1 to 8 may be structured in accordance with any of the methods of the above example methods 1 to 24.

An example machine-readable storage device 1 storing instructions, that when executed by one or more processors, cause a machine to perform operations, can comprise instructions to perform functions associated with any features of example memory devices 1 to 9 or perform methods associated with any features of example methods 1 to 24.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A method of forming a memory device, the method comprising:
recessing a portion of a dielectric isolation region, creating a corner between the dielectric isolation region and a conductive region, the conductive region being material for an active area of an access device for a memory cell of the memory device;
filling the corner with a dielectric material, the dielectric material being different from material of the dielectric isolation region;
forming a data line contact contacting the dielectric material and coupled to the conductive region; and
forming a cell contact to the memory cell contacting the dielectric material, replacing a portion of the dielectric isolation region such that the dielectric material is between the cell contact and the data line contact.

2. The method of claim 1, wherein filling the corner with the dielectric material includes forming the dielectric material by atomic layer deposition.

3. The method of claim 2, wherein the dielectric material is a non-oxide dielectric.

4. The method of claim 1, wherein forming the data line contact to the conductive region includes forming a silicon plug between the data line contact and the conductive region after recessing the conductive region.

5. The method of claim 1, wherein the method includes forming a capacitor coupled to the cell contact.

6. A method of forming a memory device, the method comprising:
forming a first opening through sacrificial dielectric regions, exposing a top of a conductive region and exposing a portion of a shallow trench isolation region adjacent to and contacting the conductive region, the conductive region being material for an active area of an access device for a memory cell of the memory device;
forming a liner of dielectric material in the first opening, covering the exposed top of the conductive region and the exposed portion of the shallow trench isolation region;
removing portions of the liner while leaving a corner of the dielectric material on the shallow trench isolation regions about the top of the conductive region;
removing portions of the conductive region, while maintaining the corner of the dielectric material on the shallow trench isolation region;
forming a data line contact contacting the corner and coupled to a remaining portion of the conductive region after removing the portions of the conductive region; and
forming a cell contact separated from the data line contact by the corner of the dielectric material.

7. The method of claim 6, wherein forming the first opening includes selectively etching the sacrificial dielectric regions substantially without etching the conductive region.

8. The method of claim 6, wherein forming the liner of dielectric material includes forming the liner by atomic layer deposition.

9. The method of claim 6, wherein removing the portions of the liner includes performing an isotropic removal of the portions of the liner.

10. The method of claim 9, wherein performing the isotropic removal includes performing a wet etch of the liner.

11. The method of claim 6, wherein the dielectric material is a non-oxide dielectric.

12. The method of claim 11, wherein the non-oxide dielectric includes one or more of a dielectric nitride or silicon carbide.

13. The method of claim 6, wherein forming the data line contact includes:
forming a conductive plug contacting the remaining portion of the conductive region; and
forming the data line contact above and contacting the conductive plug.

14. The method of claim 13, wherein the conductive plug is a polysilicon plug and the data line contact includes tungsten.

15. The method of claim 6, wherein the shallow trench isolation region includes a dielectric nitride.

16. A memory device comprising:
a memory cell having a storage element and an access device;
a data line contact coupled to the access device of the memory cell;
a cell contact coupled to the access device of the memory cell;
a shallow trench isolation region adjacent to and contacting the data line contact; and
a dielectric structure contacting the data line contact and the cell contact, the dielectric structure on and contacting the shallow trench isolation region and separating the data line contact from the cell contact.

17. The memory device of claim 16, wherein the dielectric structure is a non-oxide dielectric.

18. The memory device of claim 17, wherein the non-oxide dielectric includes one or more of a dielectric nitride or silicon carbide.

19. The memory device of claim 16, wherein the data line contact connects to a metallic data line.

20. The memory device of claim 16, wherein the access device is a transistor and the storage element is a capacitor.
